(19) United States
(12) Patent Application Publication
(10) Pub. No.: US 2009/0189140 A1
(43) Pub. Date: Jul. 30, 2009

(54) PHASE-CHANGE MEMORY ELEMENT

(75) Inventor: Frederick T. Chen, Hsinchu (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 12/020,489

(22) Filed: Jan. 25, 2008

(51) Int. Cl. H01L 45/00

(52) U.S. Cl. 257/4; 438/102; 257/E45.002

(57) ABSTRACT

A phase-change memory element with side-wall contacts is disclosed. The phase-change memory element comprises a bottom electrode. A first dielectric layer is formed on the bottom electrode. A first electrical contact is formed on the first dielectric layer and electrically connects to the bottom electrode. A second dielectric layer is formed on the first electrical contact. A second electrical contact is formed on the second dielectric layer, wherein the second electrical contact comprises an outstanding terminal. An opening passes through the second electrical contact, the second dielectric layer, and the first electrical contact. A phase-change material occupies at least one portion of the opening. A third dielectric layer is formed on and covers the second electrical contact, exposing a top surface of outstanding terminal. A top electrode is formed on the third dielectric layer, contacting the outstanding terminal.

### BACKGROUND OF THE INVENTION

1. Field of the Invention

The invention relates to a memory element, and more particularly to a phase-change memory element and method for fabricating the same.

2. Description of the Related Art

Phase-change memory technology requires high reliability, fast speeds, low current, and low operating voltage, in order to function as a viable alternative to current memory technologies such as flash and DRAM. A phase-change memory cell must therefore provide low programming current, low operating voltage, a smaller cell size, a fast phase transformation speed, and a low cost. These requirements are difficult to meet given the current state of the art.

Current phase-change memory technology makes use of heating at the interface between a metal electrode contact and the phase-change material. More effective heating requires a smaller contact area, or equivalently a smaller heating area. A benefit of this strategy is simultaneous reduction of cell size. However, reducing the area results in higher cell resistance, which increases the required driving voltage. This is clearly not desirable. Reducing heating area does not necessarily improve other performance features. There is a large temperature gradient that exists between the contact and the bulk of the phase-change material. Phase transformation speed requires good thermal uniformity within the active region of the cell. The rate of phase-change is extremely sensitive to temperature. Non-uniform heating results in a loss of reliability due to accumulation of incomplete phase-change in the programming volume.

United States Patent 20070012905 utilizes a single edge contact to the lower electrode, while the upper electrode uses a conventional planar contact. In addition, U.S. Pat. No. 6,881,603 also minimizes only the lower electrode contact area while the upper electrode contact is planar. Meanwhile, U.S. Pat. No. 6,864,503 makes use of a phase-change material spacer with top and bottom edge contacts, however, the heating area is proportional to the electrode radius, so it is relatively large, and the upper and lower electrodes are effective heat sinks.

Therefore, it is desirable to devise a phase-change memory cell structure that improves thermal uniformity as well as heating efficiency while allowing for a smaller heating area.

### BRIEF SUMMARY OF THE INVENTION

An exemplary embodiment a phase-change memory element comprises a bottom electrode. A first dielectric layer is formed on the bottom electrode. A first electrical contact is formed on the first dielectric layer and electrically connected to the bottom electrode. A second dielectric layer is formed on and covers the first electrical contact. A second electrical contact is formed on the second dielectric layer, wherein the second electrical contact comprises an outstanding terminal. An opening passes through the second electrical contact, the second dielectric layer, and lands on the first electrical contact, wherein the bottom of the opening is separated from the bottom electrode by the first dielectric layer. A phase-change material occupies at least one portion of the opening, wherein the first and second electrical contacts interface the phase-change material at the side-walls of the phase-change material. A third dielectric layer is formed on and covers the second electrical contact and exposes a top surface of the outstanding terminal. A top electrode is formed on the third dielectric layer and directly contacts the top surface of the outstanding terminal of the second electrical contact.

According to another embodiment of the invention, a method for fabricating a phase-change memory element is provided, comprising the following steps: providing a bottom electrode; forming a first dielectric layer on the bottom electrode, exposing the periphery of the top surface of the bottom electrode; conformally forming a first electrical contact on the first dielectric layer electrically connecting to the bottom electrode; forming a second dielectric layer with a trench to cover the first electrical contact; conformally forming a second electrical contact on the second dielectric layer; forming a third dielectric layer on the second electrical conduct; planarizing the third dielectric layer and the second electrical conduct to expose a top surface of an outstanding terminal of the second electrical conduct; forming an opening passing through the second electrical contact, the second dielectric layer, landing on the first electrical contact and separated from the bottom electrode by the first dielectric layer; filling a phase-change material into a part of the opening, forcing the first and second electrical contacts to interface the phase-change material at the side-walls of the phase-change material; filling a fourth dielectric layer into the opening, leaving coplanar top surfaces of the fourth dielectric layer and the outstanding terminal; and forming a top electrode formed on the third dielectric layer directly contacting the top surface of the outstanding terminal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a-1n are cross sections of a method for fabricating a phase-change memory element according to an embodiment of the invention.

FIG. 2 is a cross section of a phase-change memory element according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

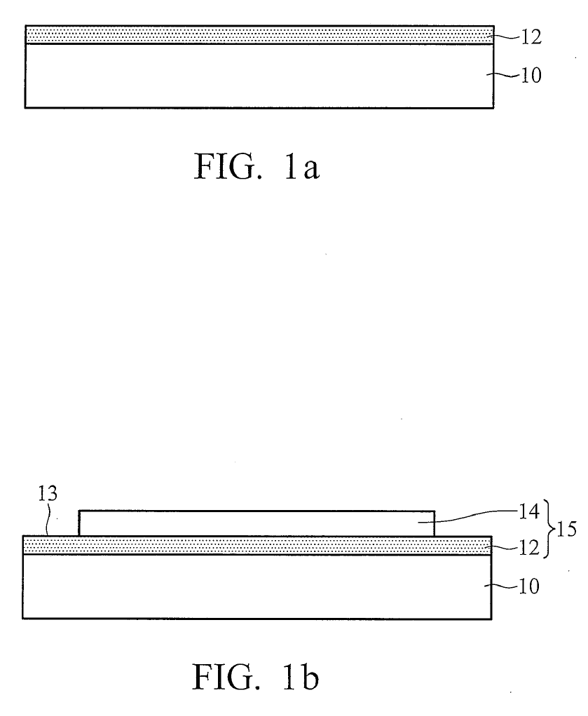

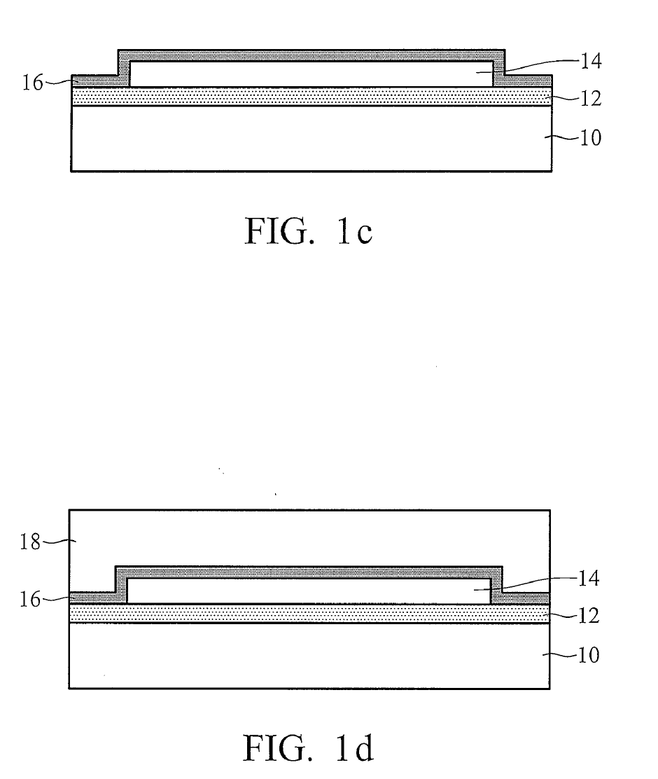

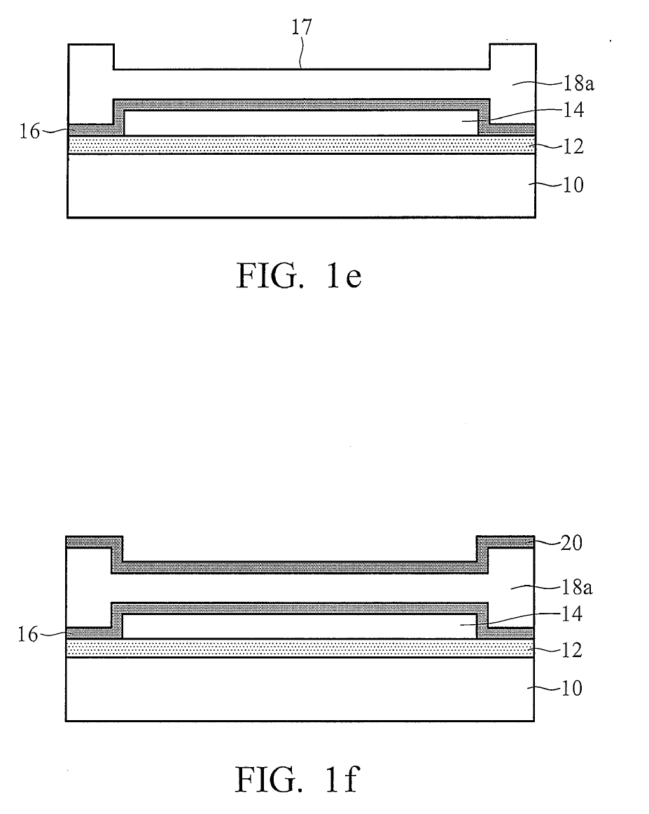

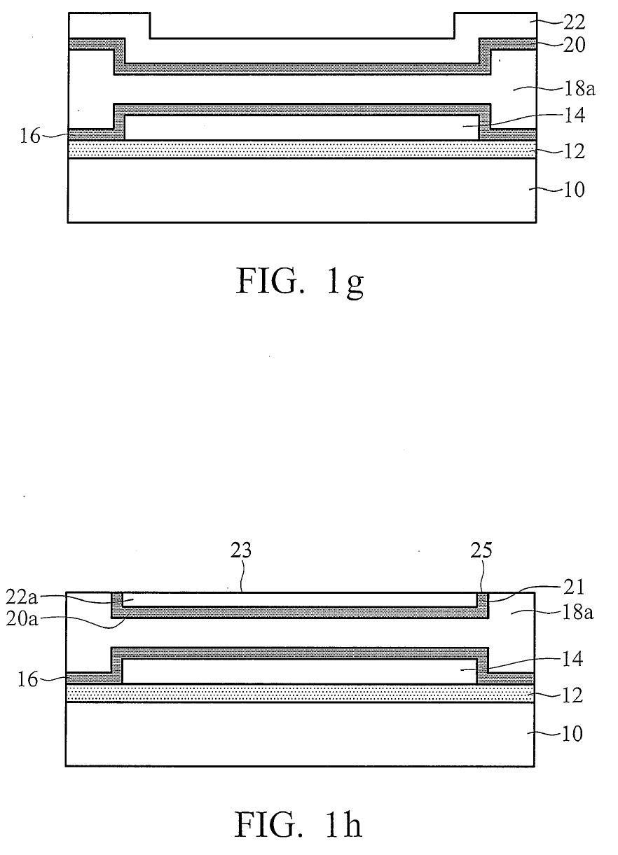

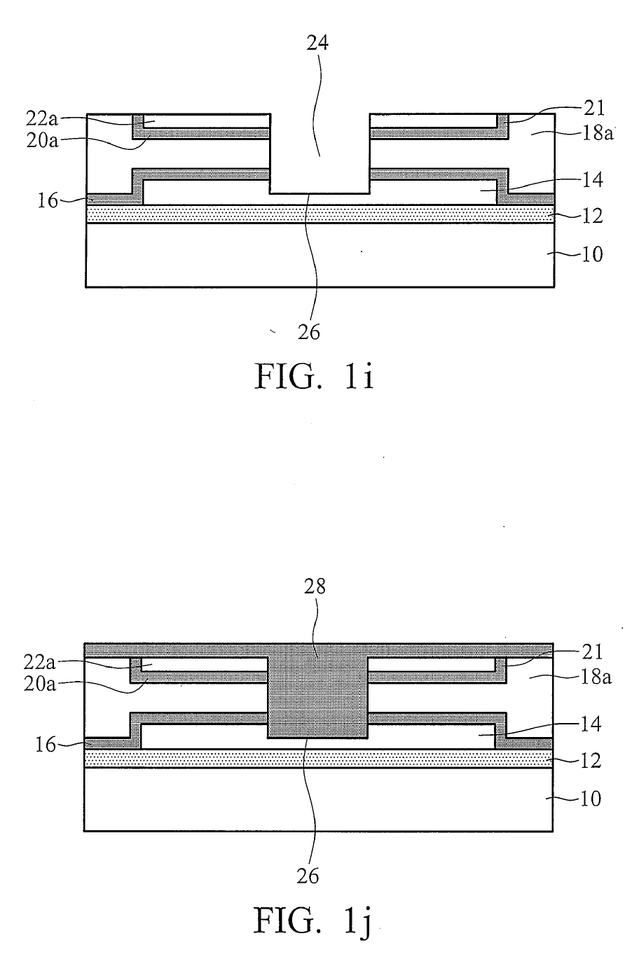

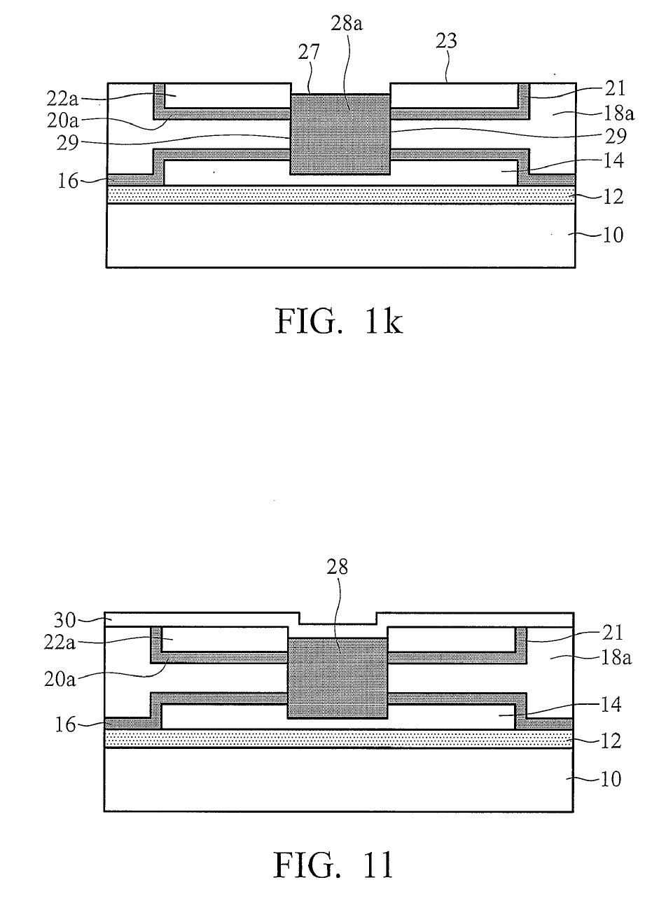

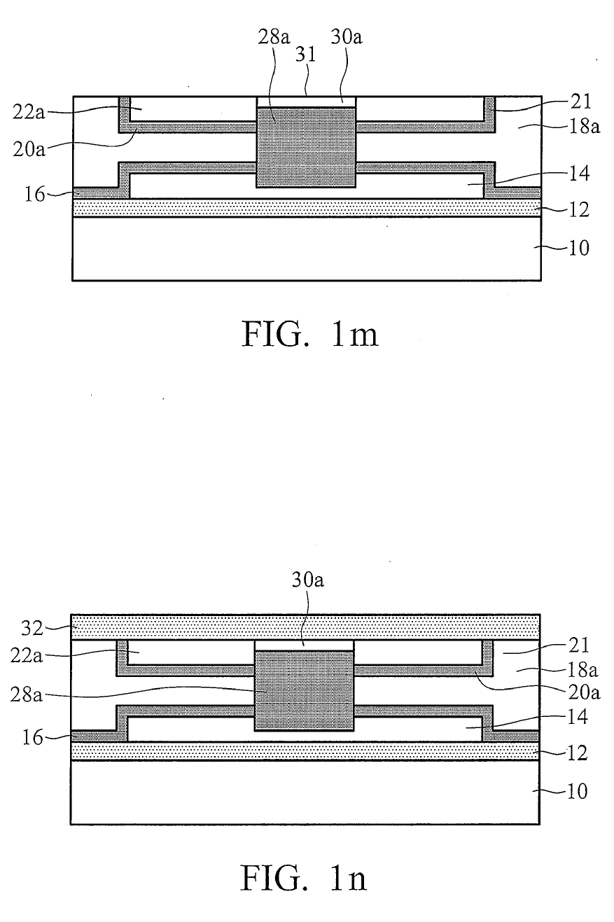

First, referring to FIG. 1a, a substrate 10 with a bottom electrode 12 formed thereon is provided. Particularly, the substrate 10 can be a substrate employed in a semiconductor process, such as silicon substrate. The substrate 10 can be a substrate comprising a complementary metal oxide semiconductor (CMOS) circuit, isolation structure, diode, or capacitor. The accompanying drawings show the substrate 10 in a plain rectangle in order to simplify the illustration. Suitable material for the bottom electrode 12, for example, is Al, W, Mo, TiN, or TiW. The isolation layer 14 can be a silicon-containing compound, such as silicon nitride or silicon oxide.

Next, referring to FIG. 1b, a dielectric layer 14 is formed on the bottom electrode 12 to expose the surrounding top surface 13 of the bottom electrode 12, wherein the bottom electrode 12 and the dielectric layer 14 formed on the bottom electrode 12 create a ladder-like configuration 15. The dielectric layer 14 can be a silicon-containing compound, such as silicon nitride or silicon oxide. Also, the dielectric layer 14 may constitute a bulk dielectric layer on top of an etch stop layer.

Next, referring to FIG. 1c, a first electrical contact 16 is conformally formed on the dielectric layer 14 to cover the ladder-like configuration 15, wherein the first electrical contact 16 is electrically connected to the bottom electrode 12 via surrounding top surface 13. Suitable material for the first electrical contact 16, for example, is Al, W, Mo, TiN, or TiW. The thickness of the first electrical contact can be 10˜50 nm.

Next, referring to FIG. 1d, a dielectric layer 18 is formed on the first electrical contact 16. The dielectric layer 18 can be a silicon-containing compound, such as silicon nitride or silicon oxide.

Next, referring to FIG. 1e, the dielectric layer 18 is etched to remain a dielectric layer 18a with a trench 17.

Next, referring to FIG. 1f, a second electrical contact 20 is conformally formed on the dielectric layer 18a to cover the side-walls and bottom of the trench 17. The thickness of the first electrical contact can be 10˜50 nm. It should be noted that the depth of the trench 17 is larger than the thickness of the second electrical contact 20.

Next, referring to FIG. 1g, a dielectric layer 22 is formed on and covers the second electrical contact 20. The dielectric layer 22 comprises silicon oxide, silicon nitride, or combinations thereof.

Next, referring to FIG. 1h, the dielectric layer 22 and the second electrical conduct 20 are subjected to a planarization process such as chemical mechanical polishing with the dielectric layer 18a serving as an etching stop layer, exposing the top surface 25 of outstanding terminals 21 of the remaining second electrical contact 20a and the top surface 23 of the remaining dielectric layer 22a. Further, the planarization process results in coplanar top surfaces 25 and 23, respectively, of the outstanding terminals 21 and remaining dielectric layer 22a.

Next, referring to FIG. 1i, an opening 24 is formed to pass through the second electrical contact 20a, the dielectric layer 22a, the first electrical contact 16 and a part of the dielectric layer 14, wherein the bottom 26 of the opening is separated from the bottom electrode 12 by the dielectric layer 14. If the dielectric layer 14 contained an etch stop layer, that could help guarantee the separation.

Next, referring to FIG. 1j, a phase change layer 28 is formed on the dielectric layer 22a and filled in the opening 24. The phase change layer 28 can comprise In, Ge, Sb, Te or combinations thereof, such as GeTe, GeSb, SbTe, GeSbTe or InGeSbTe.

Next, referring to FIG. 1k, the phase change layer 28 is etched back to form a phase change material block 28a. It should be noted that the top surface 27 of the phase change material block 28a is lower than the top surface 23 of the dielectric layer 22a. Further, the top surface 27 of the phase change material block 28a is also lower than the top surface 25 of the outstanding terminals 21. Moreover, the first and second electrical contacts 16 and 20a interface the phase-change material block 28a at the side-walls 29 of the phase-change material block 28a, wherein the dimension of the cross-section areas between the phase-change material block 28a and the first (second) electrical contacts 16 (20a) depends on the thickness of the first (second) electrical contacts 16 (20a).

Next, referring to FIG. 1l, a dielectric layer 30 is conformally formed on the dielectric layer 22a and the phase-change material block 28a. The dielectric layer 30 comprises silicon oxide, silicon nitride, or combinations thereof. It should be noted that the total thickness of the dielectric layer 30 and the phase-change material block 28a is larger than the depth of the opening 24.

Next, referring to FIG. 1m, the dielectric layer 30 is subjected to a planarization process such as chemical mechanical polishing with the dielectric layer 22a serving as an etching stop layer, exposing the top surface 25 of outstanding terminals 21 of the remaining second electrical contact 20a and the top surface 31 of the remaining dielectric layer 30a. Further, the planarization process results in coplanar top surfaces 25 and 31, respectively, of the outstanding terminals 21 and remaining dielectric layer 30a.

Finally, referring to FIG. 1n, the top electrode 32 is formed on the dielectric layer 30a and directly contacts the top surface 25 of the outstanding terminal 21 of the second electrical contact 20a. Suitable material for the top electrode 32, for example, is Al, W, Mo, TiN, or TiW.

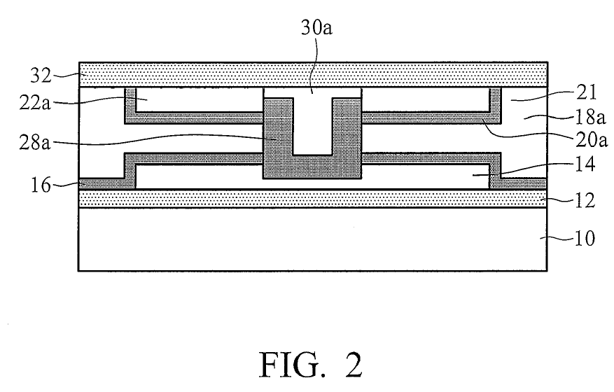

According to another embodiment of the invention, the profile of the phase-change material block 28a can be square (referring to FIG. 1n), or other shapes (such as a U-shape as seen in FIG. 2).

By forming side-wall contacts to both the top and bottom electrodes of the phase-change memory cell, heating is confined at the side-walls of the block of phase-change material, which is also the location of greatest cooling. This allows for thermal uniformity to be improved compared to devices which are heated near the center of the phase-change material. Furthermore, the voltage required can be minimized by reducing the distance between the edge contacts. Also, the heating area is reduced, hence heating efficiency improved by reducing the side-wall contact thickness as well as by reducing the width of the phase-change material.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory element, comprising
a bottom electrode;
a first dielectric layer formed on the bottom electrode, exposing the periphery of the top surface of the bottom electrode;
a first electrical contact formed on the first dielectric layer and electrically connected to the bottom electrode;
a second dielectric layer formed on and covering the first electrical contact;
a second electrical contact formed on the second dielectric layer, wherein the second electrical contact comprises an outstanding terminal;
an opening passing through the second electrical contact, the second dielectric layer, and the first electrical contact and separated from the bottom electrode by the first dielectric layer;
a phase-change material occupying at least one portion of the opening, wherein the first and second electrical contacts interface the phase-change material at the side-walls of the phase-change material;
a third dielectric layer formed on and covering the second electrical contact and exposing a top surface of the outstanding terminal; and
a top electrode formed on the third dielectric layer and directly contacting the top surface of the outstanding terminal of the second electrical contact.

2. The phase-change memory element as claimed in claim 1, wherein the bottom electrode and the first dielectric layer formed thereon create a ladder-like configuration.

3. The phase-change memory element as claimed in claim 1, wherein the thickness of the first and second electrical contact are 10˜50 nm.

4. The phase-change memory element as claimed in claim 1, wherein the bottom electrode is separated from the phase-change material by the first dielectric layer, including a possible etch stop layer.

5. The phase-change memory element as claimed in claim 1, wherein the top electrode is separated from the phase-change material by the third dielectric layer.

6. The phase-change memory element as claimed in claim 1, wherein the first electrical contact is separated from the second electrical contact by the second dielectric layer.

7. The phase-change memory element as claimed in claim 1, wherein the phase-change material comprises In, Ge, Sb, Te or combinations thereof.

8. The phase-change memory element as claimed in claim 1, wherein the first and second electrical contacts, respectively comprise Al, W, Mo, Ti, TiN, TiW or TaN.

9. The phase-change memory element as claimed in claim 1, wherein the top and bottom electrodes, respectively comprise Al, W, Mo, Ti, TiN, TiW or TaN.

10. A method for fabricating a phase-change memory element, comprising
providing a bottom electrode;
forming a first dielectric layer on the bottom electrode, exposing the periphery of the top surface of the bottom electrode;
forming a first electrical contact on the first dielectric layer electrically connected to the bottom electrode;
forming a second dielectric layer with covering the first electrical contact;
forming a second electrical contact in a trench in the second dielectric layer;
forming a third dielectric layer on the second electrical contact;
planarizing the third dielectric layer and the second electrical contact to expose a top surface of an outstanding terminal of the second electrical contact;
forming an opening passing through the second electrical contact, the second dielectric layer, and the first electrical contact and separated from the bottom electrode by the first dielectric layer;
filling a phase-change material into a part of the opening, forcing the first and second electrical contacts to interface the phase-change material at the side-walls of the phase-change material;
filling a fourth dielectric layer into the opening, resulting in coplanar top surfaces of the fourth dielectric layer and the outstanding terminal; and
forming a top electrode on the third dielectric layer directly contacting the top surface of the outstanding terminal.

11. The method as claimed in claim 10, wherein the third dielectric layer and the second electrical conduct are planarized by chemical mechanical polishing.

12. The method as claimed in claim 10, wherein the bottom electrode and the first dielectric layer formed thereon create a ladder-like configuration.

13. The method as claimed in claim 10, wherein the thickness of the first and second electrical contact are 10˜50 nm.

14. The method as claimed in claim 10, wherein the bottom electrode is separated from the phase-change material by the first dielectric layer, including a possible etch stop layer.

15. The method as claimed in claim 10, wherein the top electrode is separated from the phase-change material by the third dielectric layer.

16. The method as claimed in claim 10, wherein the first electrical contact is separated from the second electrical contact by the second dielectric layer.

17. The method as claimed in claim 10, wherein the phase-change material comprises In, Ge, Sb, Te or combinations thereof.

18. The method as claimed in claim 10, wherein the first and second electrical contacts, respectively comprise Al, W, Mo, Ti, TiN, TiW or TaN.

19. The method as claimed in claim 10, wherein the top and bottom electrodes, respectively comprise Al, W, Mo, Ti, TiN, TiW or TaN.

20. The method as claimed in claim 10, wherein the steps for forming the phase-change material comprises:
forming a phase-change layer on the third dielectric layer and filling the opening; and
etching back the phase-change layer to form the phase change material, wherein the top surface of the phase change material is lower than that of the top surface of the third dielectric layer.
